(19) United States
(12) Patent Application Publication
(10) Pub. No.: US 2011/0169053 A1
(43) Pub. Date: Jul. 14, 2011

(54) SEMICONDUCTOR DEVICE

(75) Inventor: YASUYUKI YOSHINAGA, KANAGAWA (JP)

(73) Assignee: RENESAS ELECTRONICS CORPORATION, KANAGAWA (JP)

(21) Appl. No.: 13/004,131

(22) Filed: Jan. 11, 2011

(30) Foreign Application Priority Data
Jan. 14, 2010 (JP) 2010-005910

(51) Int. Cl. H01L 29/772

(52) U.S. Cl. 257/192; 257/E29.315

(57) ABSTRACT

A semiconductor device includes an undoped InGaAs layer; an Si-doped GaAs layer formed thereover and equipped with a first recess portion; a two-layered semiconductor layer formed between the undoped InGaAs layer and the Si-doped GaAs layer, equipped with a second recess portion provided in the first recess portion, and composed of an undoped ordered InGaP layer and an undoped GaAs layer formed thereover; a C-doped GaAs layer provided over the undoped InGaAs layer in the second recess portion; and a sidewall insulating film provided between the C-doped GaAs layer and the interface between the undoped GaAs layer and the undoped ordered InGaP layer, but not provided at a portion between the undoped ordered InGaP layer and the C-doped GaAs layer.

### CROSS-REFERENCE TO RELATED APPLICATIONS

The disclosure of Japanese Patent Application No. 2010-5910 filed on Jan. 14, 2010 including the specification, drawings and abstract is incorporated herein by reference in its entirety.

### BACKGROUND

1. Field of the Invention

The present invention relates to a semiconductor device using a compound semiconductor.

2. Description of Related Art

Microwave transmitter/receiver devices to be used for mobile stations are required to satisfy both low voltage operation and low power consumption. In particular, as transmitter devices, HJFET (hetero junction field effect transistor) with a gate made of p type GaAs, which is an enhancement type field effect transistor, has been used to achieve both low voltage operation and low power consumption.

FIG. 12 is a cross-sectional view of a semiconductor device for showing the problems to be overcome by the present invention. The semiconductor device illustrated in FIG. 12 has a decreased ON resistance by forming a C-doped GaAS layer 13 as a buried gate having a two-stage recess structure.

In this semiconductor device, a two-layer structure having an undoped GaAs layer 3 and an undoped ordered InGaP layer 4 is placed on both sides of and in contact with the C-doped GaAs layer 13. The C-doped GaAs layer 13 has therebelow an Si-doped AlGaAs layer 7, which is an electron supply layer, and an undoped InGaAs layer 8, which is a channel layer, with a two-layer structure of an undoped GaAs layer 5 and an undoped AlGaAs layer 6 therebetween.

Electric charges are supplied to the undoped InGaAs layer 8 from the Si-doped AlGaAs layer 7 which has been modulation doped. Electric charges of a two-dimensional electron layer formed in the undoped InGaAs layer 8 are modulated through a pn junction gate of the C-doped GaAs layer 13. The current thus modulated is coupled to an external circuit by using a drain electrode 18 made of an Ni—AuGe—Au layer and a source electrode 19 made of an Ni—AuGe—Au layer.

FIGS. 13A to 13G illustrate a manufacturing method of the semiconductor device illustrated in FIG. 12. First, a super-lattice buffer layer 9 made of an AlGaAs layer/GaAs layer, an undoped InGaAs layer 8 which is a channel layer, an Si-doped AlGaAs layer 7 which is an electron supply layer, an undoped AlGaAs layer 6, an undoped GaAs layer 5, an undoped ordered InGaP layer 4, an undoped GaAs layer 3, an undoped AlGaAs layer 2, and an Si-doped GaAs layer 1 are formed over a semi-insulating substrate 11 made of GaAs by using metal organic chemical vapor deposition (MOCVD).

The Si-doped GaAs layer 1 and the undoped AlGaAs layer 2 are then removed using photolithography from a region, over the epitaxial substrate thus fabricated, in which a gate portion and a recess portion of a field effect transistor are to be formed. An interlayer insulating film 12 made of SiO₂ is then deposited all over the surface of the wafer (FIG. 13A).

A gate opening portion is then formed in a portion of the interlayer insulating film 12 by using photolithography and oxide-film etching (FIG. 13B). The undoped GaAs layer 3 is exposed from the opening portion of the interlayer insulating film 12. With a sulfuric acid-based etchant, the undoped GaAs layer 3 is etched off (FIG. 13C). This etching hardly removes the undoped ordered InGaP layer 4 and only about several nm thereof is etched off. This means that the undoped GaAs layer 3 is selectively etched with the InGaP layer 4 as an etching stopper.

Continuously, the InGaP layer 4 is removed using a hydrochloric acid-based etchant to form a gate recess portion (FIG. 13D). From the gate recess portion, the undoped GaAs layer 5 is exposed. A C-doped GaAs layer 13 is then formed through selective regrowth over the exposed undoped GaAs layer 5 by using MOCVD or the like (FIG. 13E). In the selective regrowth, the C-doped GaAs layer 13 is not grown over the interlayer insulating film 12.

Then, WSi is deposited, followed by patterning to form a WSi electrode 14 serving as a gate (FIG. 13F). Incidentally, the WSi electrode 14 and the C-doped GaAs layer 13 form a non-alloyed ohmic contact. The interlayer insulating film 12 over the Si-doped GaAs layer 1 is then partially removed, followed by deposition, patterning, and alloying of an Ni—AuGe—Au layer, which will be an ohmic electrode, to form a drain electrode 18 and a source electrode 19 (FIG. 13G).

The undoped GaAs layer 3 and the undoped ordered InGaP layer 4 have, at the interface therebetween, a p-type charge storage layer 15. This means that the C-doped GaAs layer 13 serving as a gate is in contact with the p-type charge storage layer 15. An electric current path from the gate is therefore formed via this p-type charge storage layer 15. Such a structure is accompanied with the drawback that a gate leakage current is large. A large gate leakage current leads to problems such as an increase in a standby current when the device is used for radio-frequency power amplifiers and a decrease in a handling power when it is used for radio-frequency switching devices.

According to T. Tanaka, K. Takano, T. Tsuchiya, and H. Sakaguchi, Journal of Crystal Growth, 221, 515-519 (2000) and K. Yamashita, K. Oe, T. Kita, O. Wada, Y. Wang, C. Geng, F. Scholz, and H. Schweizer, Jpn. J. Appl. Phys., 44, 7390-7394 (2005), the p-type charge storage layer 15 and the n-type charge storage layer 16 appear according to the following mechanism.

(a) When the InGaP layer 4 is an ordered type, polarization charges appear in the InGaP layer 4. The direction of the electric field is from the undoped InGaAs layer 8 which is a channel layer to the C-doped GaAs layer 13 which is a gate electrode.

The conduction band of the undoped GaAs layer 5 disposed above the undoped InGaAs layer 8 is therefore lowered below the Fermi level (E_{F}) and an n-type charge storage layer 16 is formed at the interface between the undoped ordered InGaP layer 4 and the undoped GaAs layer 5. According to T. Tanaka, K. Takano, T. Tsuchiya, and H. Sakaguchi, Journal of Crystal Growth, 221, 515-519 (2000), it is reported that the electron concentration is about 1×10¹² cm⁻². In addition, the GaAs layer 3 and the InGaP layer 4 have therebetween the p-type charge storage layer 15.

(b) When the InGaP layer is a disordered type, a conduction band discontinuity appears between the GaAs layer and the InGaP layer. As a result, the conduction band of GaAs is lowered below the Fermi level, leading to accumulation of electrons in the GaAs layer. In addition, the GaAs layer 3 and the InGaP layer 4 have therebetween a p-type charge storage layer 15. In either of the above cases, a charge storage layer is formed between the InGaP layer and the GaAs layer and it becomes a cause for gate leakage.

In the semiconductor device illustrated in FIG. 6 of Japanese Patent Laid-Open No. 2004-179318, an SiO₂ gate oxide film 113 is formed between a C-doped p⁺-GaAs 112 and a GaAs layer 111/InGaP layer 310 interface. A leakage current path due to the contact of the GaAs layer 111/InGaP layer 310 interface with the p-type charge storage layer is therefore insulated.

In this structure, however, the C-doped p⁺-GaAs 112 is not buried and a surface depletion layer formed on the GaAs layer 109 undesirably raises the ON resistance. Decreasing the width of the recess portion in order to decrease the ON resistance leads to a decrease in the ON resistance but increases a field strength between the C-doped p⁺-GaAs 112 serving as a gate and the drain electrode 116 or the source electrode 115. This causes a problem such as an increase in a leakage current.

### SUMMARY

Thus, the semiconductor devices described above failed to suppress an increase in the ON resistance and at the same time, reduce the leakage current.

In one aspect of the present invention, there is thus provided a semiconductor device including a channel layer of a first conductivity type, a cap layer of the first conductivity type formed over the channel layer and equipped with a first recess portion, a two-layered semiconductor layer formed between the channel layer and the cap layer, equipped with a second recess portion provided in the first recess portion, and comprised of a first semiconductor layer and a second semiconductor layer formed thereover, a semiconductor layer of a second conductivity type provided in the second recess portion over the channel region, and an insulator provided between the semiconductor layer of the second conductivity type and the two-layered semiconductor layer and covering the interface between the first semiconductor layer and the second semiconductor layer but not provided at a portion between the first semiconductor layer and the semiconductor layer of the second conductivity type.

This makes it possible to reduce the leakage current, because the interface between the first semiconductor layer and the second semiconductor layer is covered with the insulator and insulated from the semiconductor layer of the second conductivity type. In addition, the insulator is not provided at a portion between the semiconductor layer of the second conductivity type and the first semiconductor layer. This makes it possible to suppress an increase in the ON resistance because the number of carriers in the recess portion does not decrease.

According to the present invention, it is possible to provide a semiconductor device capable of suppressing an increase in the ON resistance and at the same time, reducing the leakage current; and a manufacturing method of the device.

### BRIEF DESCRIPTION OF THE DRAWINGS

FIG. 1 is a cross-sectional view showing the constitution of a semiconductor device according to a first embodiment;

FIG. 2A is a view for illustrating a manufacturing method of the semiconductor device according to the first embodiment;

FIG. 2B is a view for illustrating the manufacturing method of the semiconductor device according to the first embodiment;

FIG. 2C is a view for illustrating the manufacturing method of the semiconductor device according to the first embodiment;

FIG. 2D is a view for illustrating the manufacturing method of the semiconductor device according to the first embodiment;

FIG. 2E is a view for illustrating the manufacturing method of the semiconductor device according to the first embodiment;

FIG. 2F is a view for illustrating the manufacturing method of the semiconductor device according to the first embodiment;

FIG. 2G is a view for illustrating the manufacturing method of the semiconductor device according to the first embodiment;

FIG. 2H is a view for illustrating the manufacturing method of the semiconductor device according to the first embodiment;

FIG. 3 is a cross-sectional view showing the constitution of a semiconductor device according to a second embodiment;

FIG. 4 is a cross-sectional view showing the constitution of a semiconductor device according to a third embodiment;

FIG. 5 is a cross-sectional view showing the constitution of a semiconductor device according to a fourth embodiment;

FIG. 6 is a cross-sectional view showing the constitution of a semiconductor device according to a fifth embodiment;

FIG. 7 is a cross-sectional view showing the constitution of a semiconductor device according to a sixth embodiment;

FIG. 8 is a cross-sectional view showing the constitution of a semiconductor device according to an eighth embodiment;

FIG. 9 is a cross-sectional view showing the constitution of a semiconductor device according to the eighth embodiment;

FIG. 10 is a cross-sectional view showing the constitution of a semiconductor device according to a ninth embodiment;

FIG. 11 is a cross-sectional view showing the constitution of a semiconductor device according to a tenth embodiment;

FIG. 12 is a cross-sectional view showing the constitution of a semiconductor device for describing the problems which the present invention seeks to overcome;

FIG. 13A is a view for illustrating a manufacturing method of the semiconductor device shown in FIG. 12;

FIG. 13B is a view for illustrating the manufacturing method of the semiconductor device shown in FIG. 12;

FIG. 13C is a view for illustrating the manufacturing method of the semiconductor device shown in FIG. 12;

FIG. 13D is a view for illustrating the manufacturing method of the semiconductor device shown in FIG. 12;

FIG. 13E is a view for illustrating the manufacturing method of the semiconductor device shown in FIG. 12;

FIG. 13F is a view for illustrating the manufacturing method of the semiconductor device shown in FIG. 12;

FIG. 13G is a view for illustrating the manufacturing method of the semiconductor device shown in FIG. 12; and

FIG. 14 is a cross-sectional view showing the constitution of a semiconductor device for describing the problem which the invention seeks to overcome.

### DETAILED DESCRIPTION OF THE PREFERRED EMBODIMENTS

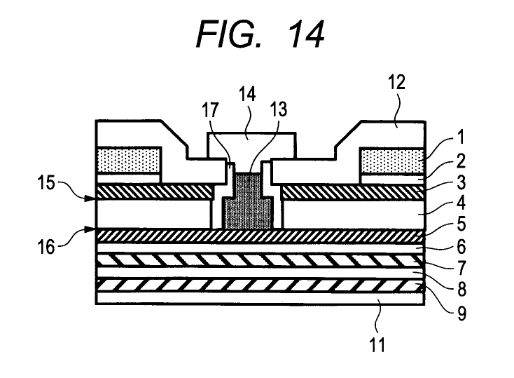

Prior to the description of the embodiments of the present invention, the reason why the present inventors have made the present invention will next be described. FIG. 14 is a cross-sectional view showing the constitution of a semiconductor device for describing the reason why the present inventors have made the present invention.

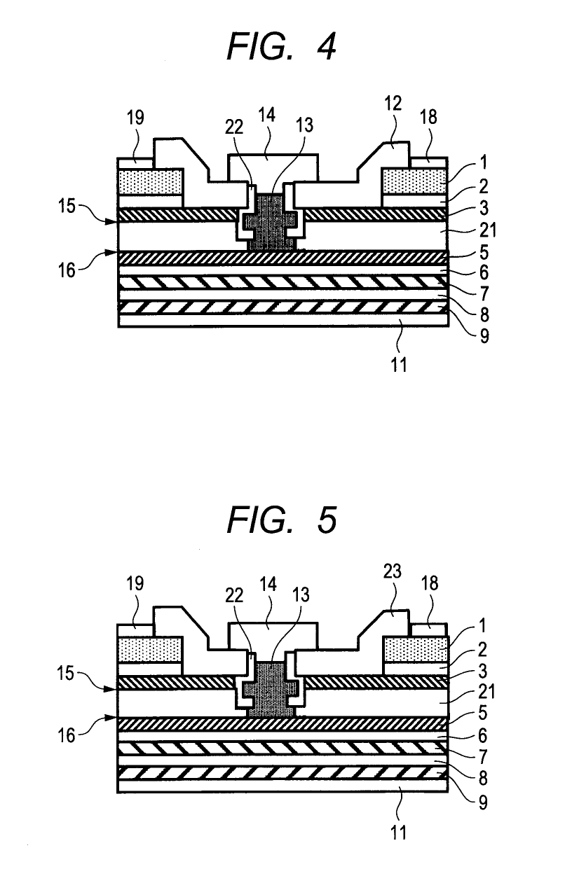

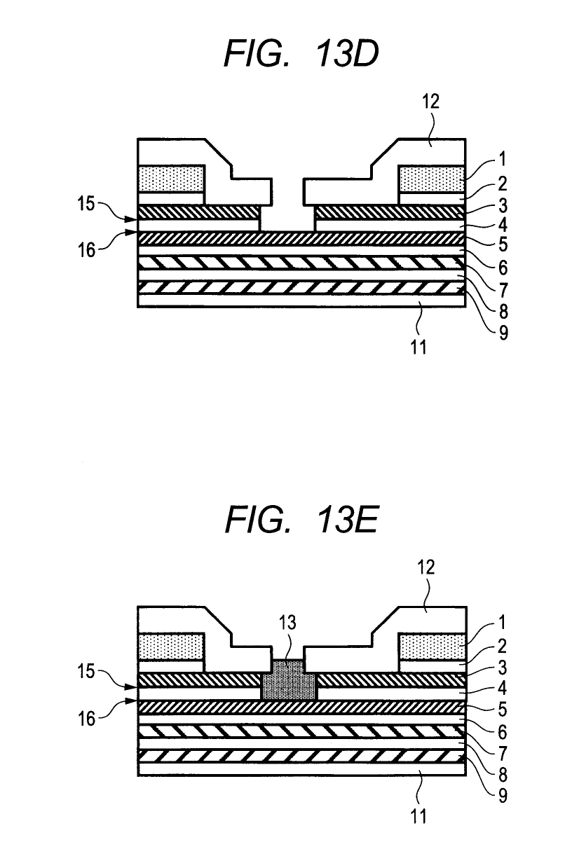

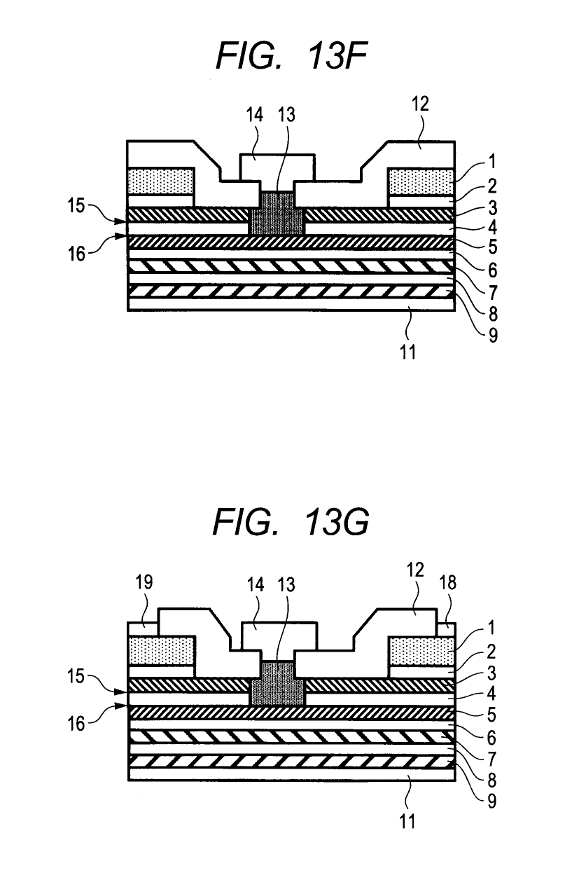

Supposing that the semiconductor device illustrated in FIG. 14 having a structure obtained by using the structure of the semiconductor device illustrated in FIG. 12 and that of the semiconductor device of Japanese Patent Laid-Open No. 2004-179318 illustrated in FIG. 6 in combination is employed in order to achieve both a low ON resistance and a low leakage current. In this semiconductor device, a C-doped GaAs layer 13 and a p-type charge storage layer 15 are insulated via a sidewall insulating film 17, by which a leakage current can be reduced.

The sidewall insulating film 17 however exists right next to the interface of the gate so that the number of carriers in the recess portion decreases due to a surface depletion layer formed on the side of an undoped GaAs layer 5 and the ON resistance increases. With a view to overcoming this problem, the present inventors therefore have made the invention described below.

### First Embodiment

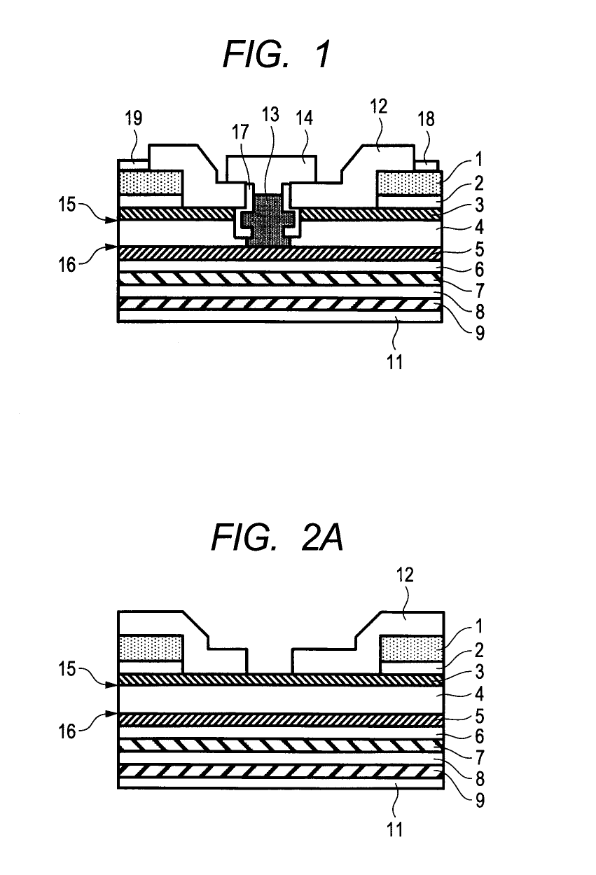

The semiconductor device according to a first embodiment of the present invention will next be described referring to FIG. 1. FIG. 1 is a cross-sectional view showing the constitution of the semiconductor device according to this embodiment. The semiconductor device of the present invention is, for example, a field effect transistor using a compound semiconductor and used for microwave transmission/reception.

As illustrated in FIG. 1, the semiconductor device according to this embodiment has an Si-doped GaAs layer 1, an undoped AlGaAs layer 2, an undoped GaAs layer 3, an undoped ordered InGaP layer 4, an undoped GaAs layer 5, an undoped AlGaAs layer 6, an Si-doped AlGaAs layer 7, an undoped InGaAs layer 8, a super-lattice buffer layer 9, a semi-insulating substrate 11, an interlayer insulating film 12, a C-doped GaAs layer 13, a WSi electrode 14, a sidewall insulating film 17, a drain electrode 18, and a source electrode 19.

The semi-insulating substrate 11 made of GaAs has, thereover, the super-lattice buffer layer 9 made of an AlGaAs layer/GaAs layer. The super-lattice buffer layer 9 has thereover the undoped InGaAs layer 8 serving as a channel layer and the Si-doped AlGaAs layer 7 serving as an electron supply layer. The Si-doped AlGaAs layer 7 has thereover the undoped AlGaAs layer 6, the undoped GaAs layer 5, the undoped ordered InGaP layer 4, the undoped GaAs layer 3, the undoped AlGaAs layer 2, and the Si-doped GaAs layer 1. They are stacked successively in this order.

The Si-doped GaAs layer 1 and the undoped AlGaAs layer 2 have therein a first recess portion. In this first recess portion, the undoped ordered InGaP layer 4 and the undoped GaAs layer 3 have therein a second recess portion. The C-doped GaAs layer 13 serving as a gate is embedded in the second recess portion. The C-doped GaAs layer 13 has thereover the WSi electrode 14. In addition, the Si-doped GaAs layer 1 has thereover the drain electrode 18 and the source electrode 19 each made of an Ni—AuGe—Au layer.

As described above, the undoped GaAs layer 3 and the undoped ordered InGaP layer 4 have therebetween the p-type charge storage layer 15. The undoped ordered InGaP layer 4 and the undoped GaAs layer 5 have therebetween the n-type charge storage layer 16.

The C-doped GaAs layer 13 and the interlayer insulating film 12, and the C-doped GaAs layer 13 and the undoped GaAs layer 3 have therebetween the sidewall insulating film 17 made of SiO₂, while this sidewall insulating film is provided partially between the C-doped GaAs layer 13 and the undoped ordered InGaP layer 4. This means that the C-doped GaAs layer 13 and the p-type charge storage layer 15 have therebetween the sidewall insulating film 17. A leakage path via the p-type charge storage layer 15 is therefore insulated, making it possible to reduce a leakage current.

The sidewall insulating film 17 is not provided at a portion between the C-doped GaAs layer 13 and the undoped ordered InGaP layer 4. In this structure, therefore, the sidewall insulating film 17 is not in contact with the undoped GaAs layer 5 formed below the C-doped GaAs layer 13 which will serve as a gate. A decrease in the number of carriers in the recess portion due to a surface depletion layer of the undoped GaAs layer 5 therefore does not occur, making it possible to suppress an increase in the ON resistance.

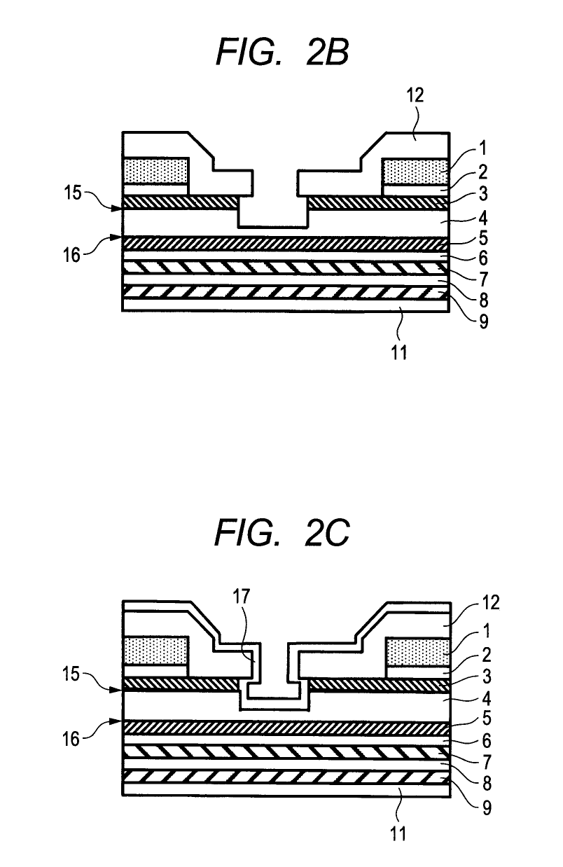

Referring to FIGS. 2A to 2H, a manufacturing method of the semiconductor device according to the present embodiment will be described. First, a super-lattice buffer layer 9 made of an AlGaAs layer/GaAs layer, an undoped InGaAs layer 8, a Si-doped AlGaAs layer 7, an undoped AlGaAs layer 6, an undoped GaAs layer 5, an undoped ordered InGaP layer 4, an undoped GaAs layer 3, an undoped AlGaAs layer 2, and an Si-doped GaAs layer 1 are formed successively over a semi-insulating substrate 11 made of GaAs by using metal organic chemical vapor deposition (MOCVD).

The Si-doped GaAs layer 1 and the undoped AlGaAs layer 2 in a region, over the epitaxial substrate thus fabricated, in which a gate portion of a field effect transistor and a recess portion are to be formed are removed using photolithography. An interlayer insulating film 12 made of SiO₂ is then deposited all over the wafer. Photolithography and oxide film etching are then performed to form a gate opening portion in a portion of the interlayer insulating film 12. As a result, the structure illustrated in FIG. 2A is formed.

From the opening portion of the interlayer insulating film 12, the undoped GaAs layer 3 is exposed. With a sulfuric acid-based etchant, the GaAs layer 3 is etched off. This etching removes only about several nm of the undoped ordered InGaP layer 4 and this layer serves as an etching stopper (FIG. 2B). A sidewall insulating film 17 is then deposited, for example, by plasma chemical deposition. The sidewall insulating film 17 covers therewith the surface of the p-type charge storage layer 15 at the interface between the undoped GaAs layer 3 and the undoped ordered InGaP layer 4 (FIG. 2C).

The sidewall insulating film 17 over the InGaP layer 4 is then removed using anisotropic dry etching. Since the etching occurs anisotropically, the sidewall insulating film 17 covering therewith the surface of the p-type charge storage layer 15 remains without being removed. The surface of it is therefore still covered with the sidewall insulating film (FIG. 2D). This means that the sidewall insulating film 17 covers therewith the side surfaces of the interlayer insulating film 12, the undoped GaAs layer 3, and the undoped ordered InGaP layer 4 in the first recess portion and the second recess portion.

The InGaP layer 4 exposed from the second recess portion is then removed with a hydrochloric acid-based etchant. In this etching, the GaAs layer 5 serves as an etching stopper against the hydrochloric acid-based etchant and as a result, the GaAs layer 5 is exposed from the surface (FIG. 2E).

Organic chemical vapor deposition or the like is then performed to cause selective growth of a C-doped GaAs layer 13 over the undoped GaAs layer 5 at the opening portion of the sidewall insulating film 17 thus formed (FIG. 2F). A WSi electrode 14 serving as a gate is then formed by depositing Wsi through sputtering and then patterning (FIG. 2G) it. Incidentally, the WSi electrode 14 and the C-doped GaAs layer 13 form a non-alloy ohmic contact.

A portion of the interlayer insulating film 12 over the Si-doped GaAs layer 1 is then removed. An Ni—AuGe—Au layer is deposited, followed by patterning and alloying to form a drain electrode 18 and a source electrode 19 (FIG. 2H). The C-doped GaAs layer 13 serving as a p gate and the p-type charge storage layer 15 formed between the GaAs layer 3 and the InGaP layer 4 are insulated with the SiO₂ insulating film 17. A leakage current through a conduction channel via the p-type charge storage layer 15 can therefore be reduced.

### Second Embodiment

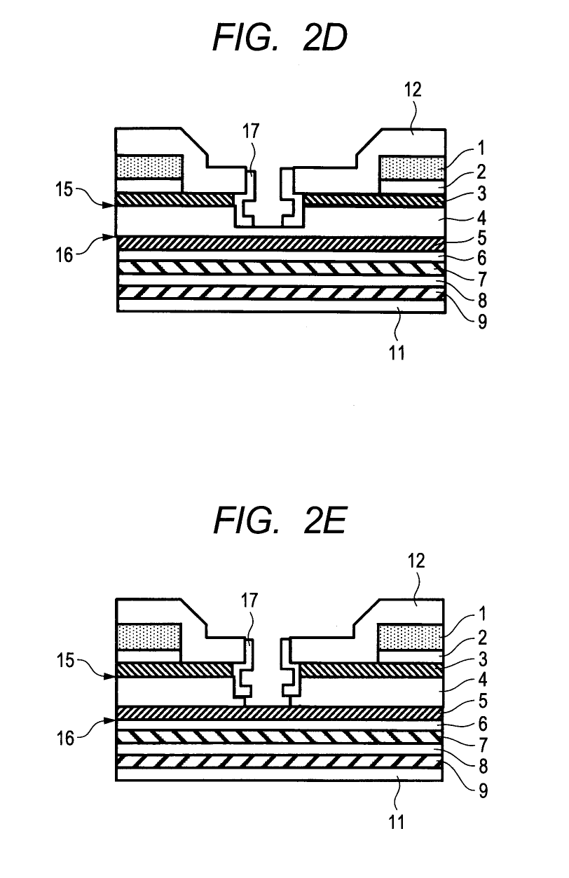

A semiconductor device according to a second embodiment will be described referring to FIG. 3. Constituting elements similar to those in FIG. 1 are denoted by the same reference numerals, and thus a description thereof will be omitted. In this embodiment, an undoped disordered InGaP layer 21 is provided instead of the undoped ordered InGaP layer 4 of the first embodiment. Also in this example, a semiconductor device having a reduced ON resistance and at the same time, having a reduced leakage current can be obtained as in the first embodiment.

### Third Embodiment

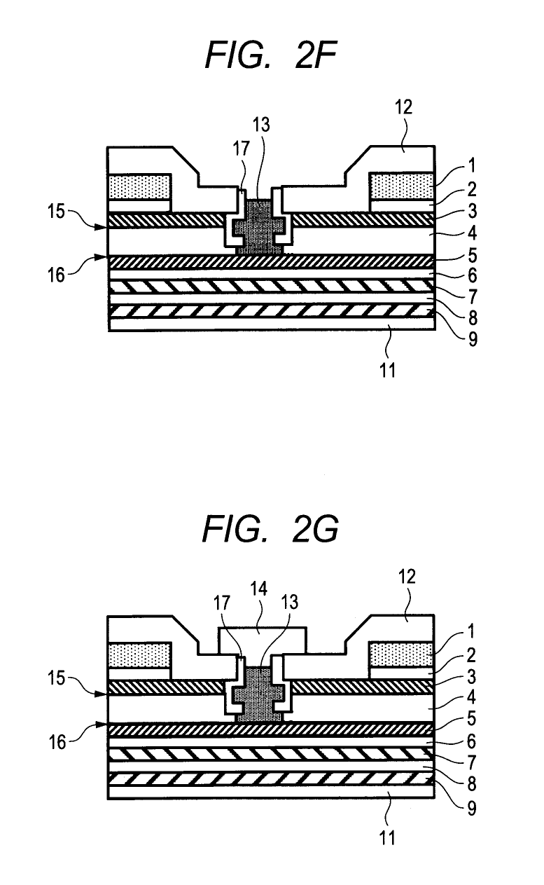

A semiconductor device according to a third embodiment will be described referring to FIG. 4. In FIG. 4, constituting elements similar to those in the above embodiment are denoted by the same reference numerals, and thus a description thereof will be omitted. In this embodiment, a sidewall insulator 22 is provided instead of the sidewall insulating film 17 of the second embodiment. As the sidewall insulator 2, SiNₓ, SiONₓ, or another insulator including a vacuum or air gap can be used.

Also in this example, a semiconductor device having a reduced ON resistance and at the same time, having a reduced leakage current can be obtained as in the first embodiment. Incidentally, in a third embodiment, the undoped disordered InGaP layer 21 may be replaced by the undoped ordered InGaP layer 4.

### Fourth Embodiment

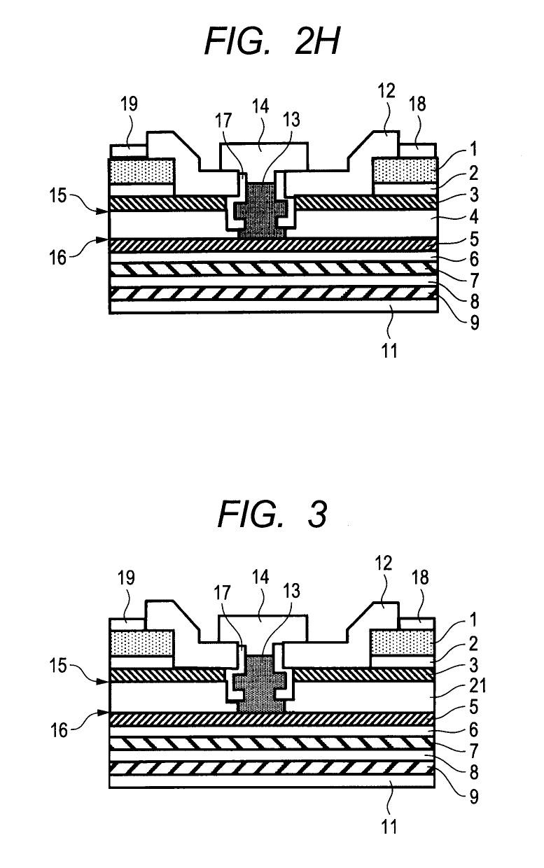

A semiconductor device according to a fourth embodiment will be described referring to FIG. 5. In FIG. 5, constituting elements similar to those in the above embodiment are denoted by the same reference numerals, and thus a description thereof will be omitted. In this embodiment, the interlayer insulating film 12 of the third embodiment is replaced by an interlayer insulator 23. As the interlayer insulator 23, SiNₓ, SiONₓ, or another insulator including a vacuum or air gap can be used.

Also in this example, a semiconductor device having a reduced ON resistance and at the same time, having a reduced leakage current can be obtained as in the first embodiment. Incidentally, in the fourth embodiment, the undoped disordered InGaP layer 21 may be replaced by the undoped ordered InGaP layer 4. In addition, the sidewall insulator 22 may be replaced by the sidewall insulating film 17.

### Fifth Embodiment

A semiconductor device according to a fifth embodiment will be described referring to FIG. 6. In FIG. 6, constituting elements similar to those in the above embodiment are denoted by the same reference numerals, and thus a description thereof will be omitted. In this embodiment, the doped GaAs layer 13 of the fourth embodiment may be replaced by a p-type compound semiconductor layer 24. As the p-type compound semiconductor layer 24, an AlGaAs layer doped with C, Zn, Mg, or the like may be used.

Also in this example, a semiconductor device having a reduced ON resistance and at the same time, having a reduced leakage current can be obtained as in the first embodiment. Incidentally, in the fifth embodiment, the undoped disordered InGaP layer 21 may be replaced by the undoped ordered InGaP layer 4. In addition, the sidewall insulator 22 may be replaced by the sidewall insulating film 17. Further, the interlayer insulator 23 may be preplaced by the interlayer insulating film 12.

### Sixth Embodiment

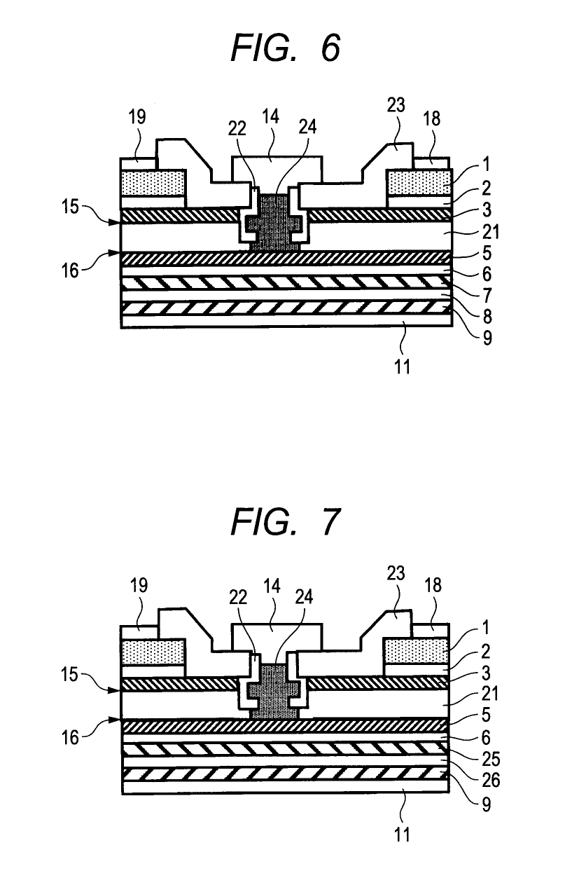

A semiconductor device according to a sixth embodiment will be described referring to FIG. 7. In FIG. 7, constituting elements similar to those in the above embodiment are denoted by the same reference numerals, and thus a description thereof will be omitted. In this embodiment, an electron supply layer 25 is provided instead of the Si-doped AlGaAs layer 7 of the fifth embodiment and a channel layer 26 is provided as the undoped InGaAs layer 8.

As the electron supply layer 25, an Si-doped InAlAs layer or another compound semiconductor layer which supplies electrons to the channel layer 26 can be used. As the channel layer 26, an Si-doped InGaAs layer or another compound semiconductor layer which becomes a channel layer can be used.

Either of the Si-doped AlGaAs layer 7 or the undoped InGaAs layer 8 may be replaced by the electron supply layer 25 or the electron running layer 26. Alternatively, both of them may be replaced. When the channel layer 26 also serves as an electron supply layer, the electron supply layer 25 can be omitted.

Also in this embodiment, as described above, the undoped disordered InGaP layer 21 may be replaced by the undoped ordered InGaP layer 4. In addition, the sidewall insulator 22 may be replaced by the sidewall insulating film 17. Further, the interlayer insulator 23 may be preplaced by the interlayer insulating film 12. The p-type compound semiconductor layer 24 may be replaced by the C-doped GaAs layer 13.

### Seventh Embodiment

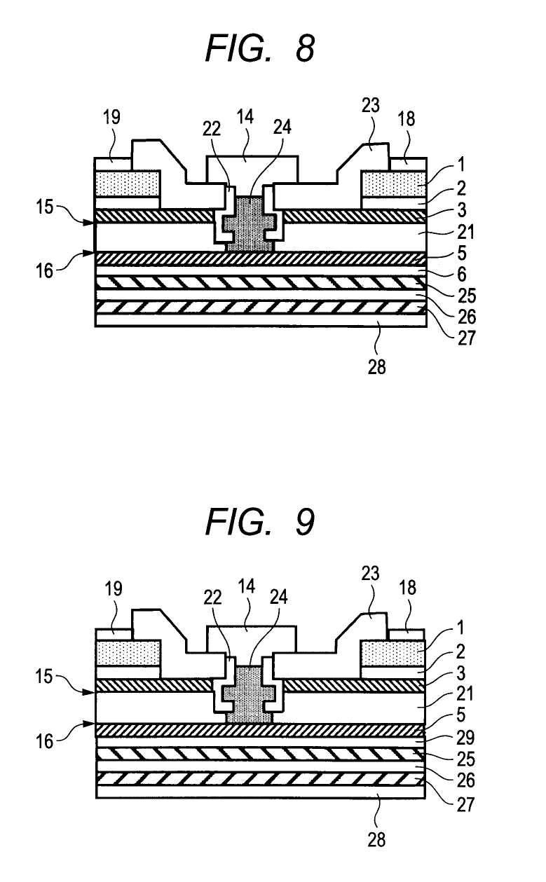

A semiconductor device according to a seventh embodiment will be described referring to FIG. 8. In FIG. 8, constituting elements similar to the embodiments described above are denoted by the same reference numerals, and thus description thereof will be omitted. In this embodiment, a semiconductor layer 27 is provided instead of the super-lattice buffer layer 9 of the sixth embodiment and a substrate 28 is provided instead of the half-insulating substrate 11.

As the semiconductor layer 27, a layer composed of one or more selected from GaAs and the other semiconductors can be used. As the substrate 28, a semiconductor substrate made of Si, InP, or the like, or an insulator substrate made of Al₂O₃ or the like can be used.

Incidentally, either of the semiconductor layer 27 or the substrate 28 may be replaced by the super-lattice buffer layer 9 or the semi-insulting substrate 11. Alternatively, both of them may be replaced. As described above, also in this embodiment, the undoped disordered InGaP layer 21 may be replaced by the undoped ordered InGaP layer 4. The sidewall insulator 22 may be replaced by the sidewall insulating film 17. Further, the interlayer insulator 23 may be replaced by the interlayer insulating film 12. The p-type compound semiconductor layer 24 may be replaced by the C-doped GaAs layer 13. The Si-doped AlGaAs layer 7 the electron supply layer 25 and the channel layer 26 may be replaced by the Si-doped AlGaAs layer 7 and the undoped InGaAs layer 8, respectively.

### Eighth Embodiment

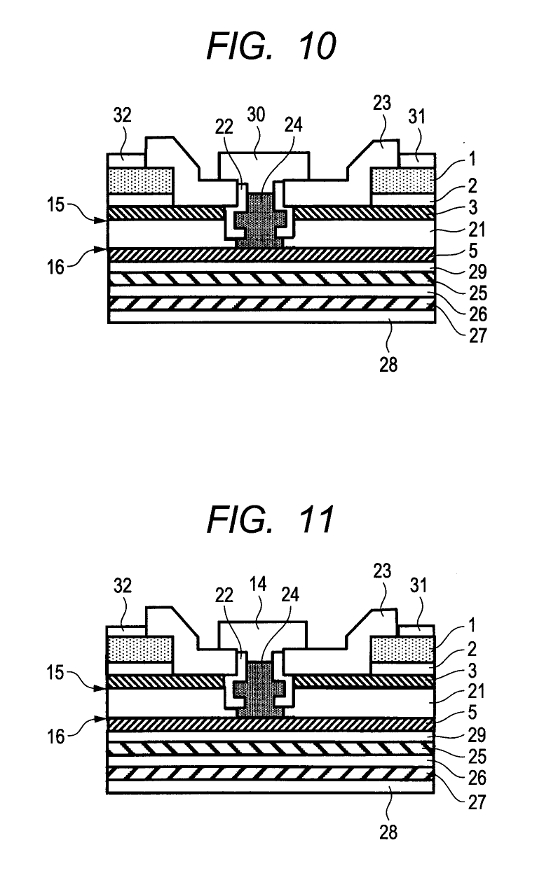

A semiconductor device according to an eighth embodiment will be described referring to FIG. 9. In FIG. 9, constituting elements similar to those in the above embodiment are denoted by the same reference numerals, and thus a description thereof will be omitted. In this embodiment, a semiconductor layer 29 is provided instead of the undoped AlGaAs layer 6 of the seventh embodiment. As the semiconductor layer 29, an Si-doped or undoped AlGaAs layer or another semiconductor layer can be used.

Incidentally, either of the super-lattice buffer layer 9 or the semi-insulating substrate 11 may be replaced by the semiconductor layer 27 or the substrate 28. Alternatively, both of them may be replaced. As described above, also in this embodiment, the undoped disordered InGaP layer 21 may be replaced by the undoped ordered InGaP layer 4. The sidewall insulator 22 may be replaced by the sidewall insulating film 17. Further, the interlayer insulator 23 may be replaced by the interlayer insulating film 12. The p-type compound semiconductor layer 24 may be replaced by the C-doped GaAs layer 13. The electron supply layer 25 and the channel layer 26 may be replaced by the Si-doped AlGaAs layer 7 and the undoped InGaAs layer 8, respectively.

### Ninth Embodiment

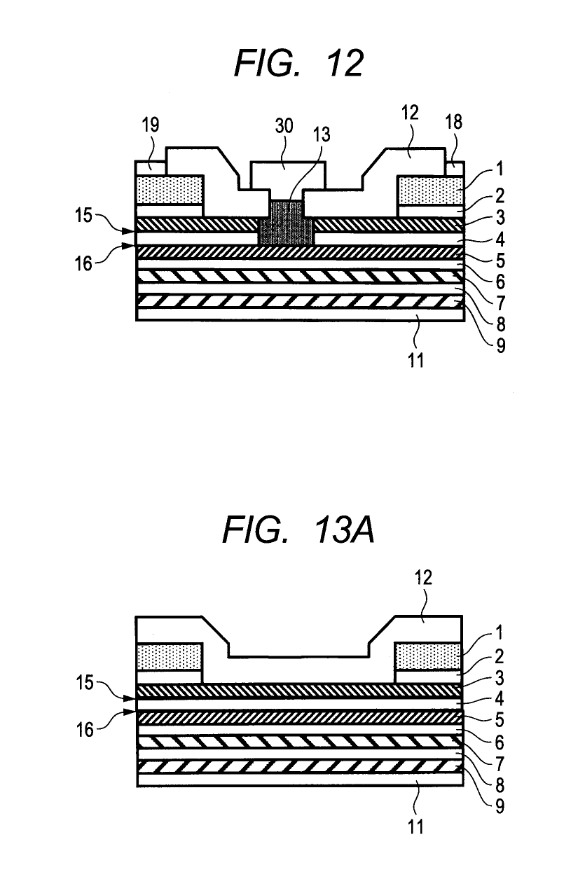

A semiconductor device according to a ninth embodiment will be described referring to FIG. 10. In FIG. 10, constituting elements similar to those in the above embodiment are denoted by the same reference numerals, and thus a description thereof will be omitted. In this embodiment, a metal layer 30 is provided instead of the WSi electrode 14 of Embodiment 8 and a metal layer 31 and a metal 32 are provided instead of the drain electrode 18 and the source electrode 19, respectively.

As the metal layer 30, a layer made of Ti, Au, Pt, Nt, Mo, or another metal and forming an ohmic contact with the p-type compound semiconductor layer 24 or the C-doped GaAs layer 13 can be used. As the metal layer 31 and the metal layer 32, a layer made of Mo or another metal and forming an ohmic contact with the Si-doped GaAs layer 11 can be used. Any one or more or all of the WSi electrode 14, the drain electrode 18, and the source electrode 19 may be replaced with the elements described above, respectively.

### Tenth Embodiment

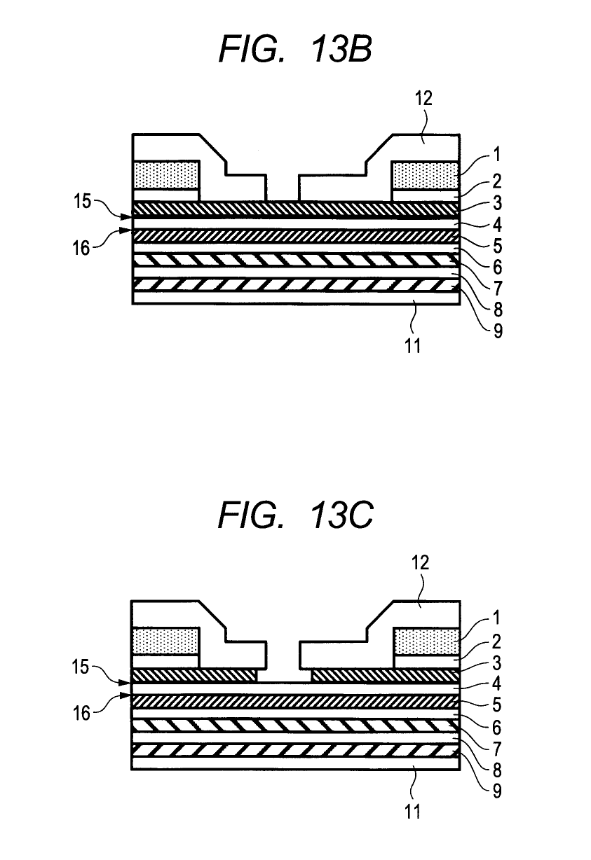

A semiconductor device according to an tenth embodiment will be described referring to FIG. 11. In FIG. 11, constituting elements similar to those in the above embodiment are denoted by the same reference numerals, and thus a description thereof will be omitted. In this embodiment, the semiconductor device of Embodiment 9 is provided as a diode. Also in this embodiment, a semiconductor device having a reduced ON resistance and at the same time, having a reduced leakage current can be obtained.

Either of the semiconductor layer 27 or the substrate 28 may be replaced by the super-lattice buffer layer 9 or the semi-insulating substrate 11. Alternatively, both of them may be replaced. As described above, also in this embodiment, the undoped disordered InGaP layer 21 may be replaced by the undoped ordered InGaP layer 4. The sidewall insulator 22 may be replaced by the sidewall insulating film 17. Further, the interlayer insulator 23 may be replaced by the interlayer insulating film 12.

The p-type compound semiconductor layer 24 may be replaced by the C-doped GaAs layer 13. The Si-doped AlGaAs layer 7 and the undoped InGaAs layer 8 may be replaced by the electron supply layer 25 and the channel layer 26, respectively. The metal layer 30 may be replaced by the WSi electrode 14 and the metal layer 31 and the metal layer 32 may be replaced by the drain electrode 18 and the source electrode 19, respectively.

The invention is not limited to or by the embodiments described above but can be changed without departing from the scope of the invention.

1. A semiconductor device, comprising:
a channel layer of a first conductivity type,
a cap layer of the first conductivity type formed over the channel layer and equipped with a first recess portion,
a two-layered semiconductor layer formed between the channel layer and the cap layer, equipped with a second recess portion provided in the first recess portion, and comprised of a first semiconductor layer and a second semiconductor layer formed thereover,
a semiconductor layer of a second conductivity type provided in the second recess portion over the channel region, and
an insulator provided between the semiconductor layer of the second conductivity type and the two-layered semiconductor layer and covering an interface between the first semiconductor layer and the second semiconductor layer but not provided at a portion between the first semiconductor layer and the semiconductor layer of the second conductivity type.

2. The semiconductor device according to claim 1, wherein electrons in the channel layer are modulated by a potential applied to the semiconductor layer of the second conductivity type.

3. The semiconductor device according to claim 1, wherein the channel layer has a channel layer and an electron supply layer adjacent thereto.

4. The semiconductor device according to claim 2, wherein the channel layer has a channel layer and an electron supply layer adjacent thereto.
